(19) United States
(12) Patent Application Publication
(10) Pub. No.: US 2009/0127611 A1
(43) Pub. Date: May 21, 2009

(54) NON-VOLATILE MEMORY DEVICE AND MEMORY CARD AND SYSTEM INCLUDING THE SAME

(75) Inventors: Ki-yeon Park, Seoul (KR); Cha-young Yoo, Gyeonggi-do (KR); Sung-hae Lee, Gyeonggi-do (KR); Jun-noh Lee, Gyeonggi-do (KR); Min-kyung Ryu, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/120,443

(22) Filed: May 14, 2008

(30) Foreign Application Priority Data
Nov. 21, 2007 (KR) 10-2007-0119301

(51) Int. Cl. H01L 29/792; H01L 29/788

(52) U.S. Cl. 257/316; 257/326; 257/E29.309; 257/E29.3

(57) ABSTRACT

A non-volatile memory device includes a semiconductor layer including source and drain regions and a channel region between the source and drain regions; a tunneling insulating layer on the channel region of the semiconductor layer; a charge storage layer on the tunneling insulating layer; a blocking insulating layer on the charge storage layer and including a first oxide layer with a first thickness, a high-k dielectric layer, and a second oxide layer with a second thickness different from the first thickness that are stacked sequentially on the charge storage layer; and a control gate on the blocking insulating layer.

### CROSS-REFERENCE TO RELATED PATENT APPLICATION

This application claims priority under 35 U.S.C. §119 from Korean Patent Application No. 10-2007-0119301, filed on Nov. 21, 2007, in the Korean Intellectual Property Office, the disclosure of which is incorporated herein in its entirety by reference.

### BACKGROUND

1. Field of the Invention

The present invention relates to semiconductor devices, and more particularly to non-volatile memory devices and memory cards and systems including the same.

2. Description of the Related Art

Non-volatile semiconductor memory devices can retain stored data even if their power supply is interrupted. In recent years, owing to the increased demand for compact portable electronic products, such as portable multimedia reproduction devices, digital cameras, and personal digital assistants (PDAs), research into high-capacity, highly-integrated non-volatile memory devices has rapidly progressed. Non-volatile memory devices may be classified into programmable read-only memories (PROMs), erasable and programmable read-only memories (EPROMs), and electrically erasable and programmable read-only memories (EEPROMs). A typical example of a non-volatile memory device is a flash memory device.

Flash memory devices typically perform erase operations and rewrite operations in block units. Also, since flash memory devices are capable of high integration and may have good data retention characteristics, flash memory devices may function as a main memory in a system and can be used with an ordinary dynamic random access memory (DRAM) interface. Furthermore, flash memory devices may have both high integration and high capacity and be fabricated inexpensively, so that flash memory devices may be used as a subsidiary storage device in place of a conventional hard disk.

A cell transistor of a conventional flash memory includes a tunneling insulating layer disposed on a semiconductor substrate, a charge storage layer (e.g., a floating gate), a blocking insulating layer, and a control gate that are stacked sequentially. A flash memory device typically performs a write operation using a hot electron injection or Fowler-Nordheim tunneling (F-N tunneling) mechanism, and typically performs an erase operation through the F-N tunneling mechanism.

Cell characteristics of a flash memory device may depend on the thickness of the tunneling insulating layer, a contact area between the charge storage layer and the semiconductor substrate, a contact area between the charge storage layer and the control gate, and/or the thickness of the blocking insulating layer. The cell characteristics of the flash memory device may include program speed, erase speed, the distribution of program cells, and the distribution of erase cells. Also, some other characteristics related to the reliability of cells of the flash memory device include program/erase endurance and data retention.

Typically, the program speed and the erase speed of a flash memory device are determined by a ratio of a tunneling capacitance Cₜᵤₙₙₑₗ between the semiconductor substrate and the charge storage layer to an inter-gate capacitance C_{inter-gate} between the charge storage layer and the control gate and proportional to a coupling ratio shown in Equation 1:

$$Coupling ratio = \frac{{C}_{block}}{{C}_{tunnel} + {C}_{block}} \qquad ( 1 )$$

When an operating voltage is maintained constant, the coupling ratio should be increased to obtain a high program speed and a high erase speed. Therefore, to increase the coupling ratio, the capacitance Cₜᵤₙₙₑₗ can be reduced or a capacitance C_{block} of the blocking insulating layer can be increased.

In particular, as the integration density of flash memory devices increases, undesired coupling interference between adjacent charge storage layers can increase. In order to reduce the coupling interference, a method for reducing an overlap area between the adjacent charge storage layers by lowering the height of the charge storage layers has been proposed. However, in this method, the capacitance C_{block} of the blocking insulating layer decreases, thereby reducing the coupling ratio, which corresponds to the capability of the charge storage layer to transmit a voltage to the control gate. As a result, the program and/or erase speed of the flash memory device may be degraded.

In order to overcome the foregoing drawbacks, a method for reducing an equivalent oxide thickness (EOT) by forming an inter-poly dielectric (IPD) layer as a blocking insulating layer has been proposed. The IPD layer may be a multiple layer, such as an oxide-nitride-oxide (ONO) layer. Although the IPD layer has physically a small thickness, the IPD layer has a high EOT due to its high dielectric constant. Accordingly, even though the thickness of the blocking insulating layer is reduced, the capacitance C_{block} of the blocking insulating layer is increased to improve the coupling ratio. However, since a flash memory device requires a high bias voltage unlike in a DRAM, leakage current may increase. As a result, a program/erase endurance characteristic and/or a data retention characteristic of the device may be degraded, thereby jeopardizing the reliability of the flash memory device.

### SUMMARY

Some embodiments of the present invention provide a non-volatile memory device including a semiconductor layer including source and drain regions and a channel region between the source and drain regions, a tunneling insulating layer on the channel region of the semiconductor layer, a charge storage layer on the tunneling insulating layer, a blocking insulating layer on the charge storage layer and including a first oxide layer with a first thickness, a high-k dielectric layer, and a second oxide layer with a second thickness different from the first thickness that are stacked sequentially, and a control gate on the blocking insulating layer.

The first thickness may be greater than the second thickness. The first thickness may be more than 1.0 times as great as the second thickness. The first thickness may range from about 25 Å to about 80 Å, and the second thickness may range from about 25 Å to about 80 Å.

The high-k dielectric layer may include a dielectric material having a higher dielectric constant than the first and second oxide layers. Also, the high-k dielectric layer may include a dielectric material having a dielectric constant of 8 or higher. The high-k dielectric layer may be a single layer including aluminum oxide (Al₂O₃), yttrium oxide (Y₂O₃), zirconium silicon oxide (ZrSiₓO_{y}), hafnium silicon oxide (HfSiₓO_{y}), lanthanum oxide (La₂O₃), zirconium oxide (ZrO₂), hafnium oxide (HfO₂), tantalum oxide (Ta₂O₃), praseodymium oxide (Pr₂O₃), and/or titanium oxide (TiO₂). Alternatively, the high-k dielectric layer may be a single layer including at least two materials selected from the group consisting of aluminum oxide (Al₂O₃), yttrium oxide (Y₂O₃), zirconium silicon oxide (ZrSiₓO_{y}), hafnium silicon oxide (HfSiₓO_{y}), lanthanum oxide (La₂O₃), zirconium oxide (ZrO₂), hafnium oxide (HfO₂), tantalum oxide (Ta₂O₃), praseodymium oxide (Pr₂O₃), and titanium oxide (TiO₂). Alternatively, the high-k dielectric layer may be a multiple layer obtained by stacking a plurality of layers, each layer including aluminum oxide (Al₂O₃), yttrium oxide (Y₂O₃), zirconium silicon oxide (ZrSiₓO_{y}), hafnium silicon oxide (HfSiₓO_{y}), lanthanum oxide (La₂O₃), zirconium oxide (ZrO₂), hafnium oxide (HfO₂), tantalum oxide (Ta₂O₃), praseodymium oxide (Pr₂O₃), and/or titanium oxide (TiO₂).

The high-k dielectric layer may have a lower bandgap than silicon oxide. Also, the high-k dielectric layer may have a thickness of about 30 Å to about 100 Å.

The tunneling insulating layer may include a silicon oxide (SiO₂) layer, a silicon nitride (Si₃N₄) layer, a silicon oxynitride (SiON) layer, a hafnium oxide (HfO₂) layer, a hafnium silicon oxide (HfSiₓO_{y}) layer, an aluminum oxide (Al₂O₃) layer, a zirconium oxide (ZrO₂) layer, and a combination thereof.

The charge storage layer may be a floating gate or a charge trap layer. When the charge storage layer is a floating gate, the floating gate may include polysilicon. When the charge storage layer is a charge trap layer, the charge trap layer may include a silicon oxide (SiO₂) layer, a silicon nitride (Si₃N₄) layer, a silicon oxynitride (SiON), a hafnium oxide (HfO₂) layer, a zirconium oxide (ZrO₂) layer, a tantalum oxide (Ta₂O₃) layer, a titanium oxide (TiO₂) layer, a hafnium aluminum oxide (HfAlₓO_{y}) layer, a hafnium tantalum oxide (HfTaₓO_{y}) layer, a hafnium silicon oxide (HfSiₓO_{y}) layer, an aluminum nitride (AlₓN_{y}) layer, and/or an aluminum gallium nitride (AlGaN) layer.

The control gate may include polysilicon, Al, Ru, TaN, TiN, W, WN, HfN, WSiₓ, and/or a combination thereof.

The semiconductor layer may include silicon, silicon-on-insulator (SOI), silicon-on-sapphire, germanium, silicon-germanium, and/or gallium-arsenide.

According to further embodiments of the present invention, there is provided a card including a memory including a non-volatile memory device including a semiconductor layer including source and drain regions and a channel region between the source and drain regions, a tunneling insulating layer on the channel region of the semiconductor layer, a charge storage layer on the tunneling insulating layer, a blocking insulating layer on the charge storage layer and including a first oxide layer with a first thickness, a high-k dielectric layer, and a second oxide layer with a second thickness different from the first thickness that are stacked sequentially, and a control gate on the blocking insulating layer, and a controller configured to control the memory, including sending and receiving data to and from the memory.

According to yet further embodiments of the present invention, there is provided a system including a non-volatile memory device including a semiconductor layer including source and drain regions and a channel region between the source and drain regions, a tunneling insulating layer on the channel region of the semiconductor layer, a charge storage layer on the tunneling insulating layer, a blocking insulating layer on the charge storage layer and including a first oxide layer with a first thickness, a high-k dielectric layer, and a second oxide layer with a second thickness different from the first thickness that are stacked sequentially, and a control gate on the blocking insulating layer, a processor configured to send and receive data to and from the memory via a bus, and an input/output device configured to send and receive data to and from the bus.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a cross-sectional view of a non-volatile memory device according to some embodiments of the present invention;

FIGS. 2A and 2B are graphs of an applied voltage relative to equivalent oxide thickness (EOT) under a low leakage current condition and a high leakage current condition, respectively, which are obtained after a leakage current is measured in response to an applied voltage;

FIG. 3A is a graph of a variation in a threshold voltage measured after a constant voltage stress (CVS) test and a high-temperature stability (HTS) test are performed during a program operation;

FIG. 3B is a graph of a variation in a threshold voltage measured after a CVS test and an HTS test are performed during an erase operation;

FIG. 4 is a graph of a trap density measured during program and erase operations;

FIG. 5A is a graph of a variation in an accumulated threshold voltage relative to a voltage stress application time when a low voltage is applied during a program operation;

FIG. 5B is a graph of a variation in an accumulated threshold voltage relative to a voltage stress application time when a high voltage is applied during an erase operation;

FIG. 6 is a graph of a variation in a threshold voltage when the polarity of an applied voltage is periodically reversed, that is, when program operation and erase operations are performed periodically;

FIG. 7 is a schematic view of a memory card according to some embodiments of the present invention; and

FIG. 8 is a schematic view of a system according to some embodiments of the present invention.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout. It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

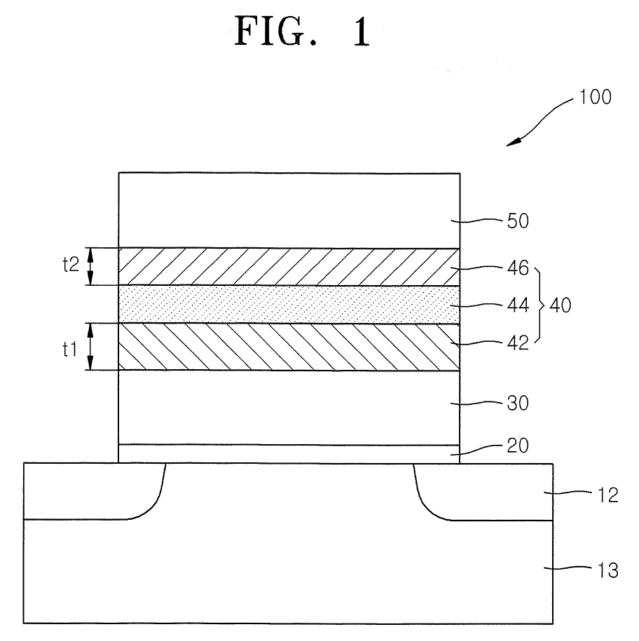

FIG. 1 is a schematic cross-sectional view of a non-volatile memory device 100 according to some embodiments of the present invention.

Referring to FIG. 1, the non-volatile memory device 100 includes a stacked structure disposed on a semiconductor layer 13 including active regions 12 doped with conductive impurity ions (hereinafter, impurity regions 12). The stacked structure includes a tunneling insulating layer 20, a charge storage layer 30, a blocking insulating layer 40, and a control gate 50 that are stacked sequentially.

The semiconductor layer 13 may be a semiconductor substrate, such as a silicon, silicon-on-insulator (SOI), silicon-on-sapphire, germanium, silicon-germanium, and/or gallium-arsenide substrate.

The impurity regions 12 may be used as source and drain regions and may define a channel region between the source and drain regions. Although not shown in the drawings, the semiconductor layer 13 may include a device isolation layer, which is obtained using a shallow trench isolation (STI) technique, and a well region, which is formed using an ion implantation process.

The tunneling insulating layer 20 is disposed on the substrate 10 and contacts the impurity regions 12. The tunneling insulating layer 20 may be formed using a dry oxidation technique and/or a wet oxidation technique. For example, in the case of the wet oxidation technique, the substrate including the impurity regions 20 may be wet oxidized at a temperature of about 700 to 800° C. and annealed at a temperature of about 900° C. in a nitrogen atmosphere for 20 to 30 minutes, thereby forming the tunneling insulating layer 20. The tunneling insulating layer may be formed to a thickness of, for example, 50 to 500 Å. Also, the tunneling insulating layer 20 may be a single layer or a multiple layer with different energy bandgaps. The tunneling insulating layer 20 may include a silicon oxide (SiO₂) layer, a silicon nitride (Si₃N₄) layer, a silicon oxynitride (SiON) layer, a hafnium oxide (HfO₂) layer, a hafnium silicon oxide layer (HfSiₓO_{y}) layer, an aluminum oxide (Al₂O₃) layer, a zirconium oxide (ZrO₂) layer, and/or a combination thereof. However, the formation method, structure, thickness, and material of the tunneling insulating layer 20 are only described as examples, and the present invention is not limited thereto.

The charge storage layer 30 is disposed on the tunneling insulating layer 20. The charge storage layer 30 may be a floating gate or a charge trap layer. When the charge storage layer 30 is a floating gate, the floating gate may be formed using a chemical vapor deposition (CVD) technique. For example, polysilicon may be deposited by low-pressure CVD (LPCVD) using SiH₄ gas or Si₂H₆ and PH₆ gases to form the floating gate. The floating gate may be formed to a thickness of, for example, about 500 Å to about 2000 Å. When the charge storage layer 30 is a charge trap layer, the charge trap layer may include a silicon oxide (SiO₂) layer, a silicon nitride (Si₃N₄) layer, a silicon oxynitride (SiON), a hafnium oxide (HfO₂) layer, a zirconium oxide (ZrO₂) layer, a tantalum oxide (Ta₂O₃) layer, a titanium oxide (TiO₂) layer, a hafnium aluminum oxide (HfAlₓO_{y}) layer, a hafnium tantalum oxide (HfTaₓO_{y}) layer, a hafnium silicon oxide (HfSiₓO_{y}) layer, an aluminum nitride (AlₓN_{y}) layer, and/or an aluminum gallium nitride (AlGaN) layer. However, the formation method, structure, thickness, and material of the charge storage layer 30 are only described as examples, and the present invention is not limited thereto.

The blocking insulating layer 40 is disposed on the charge storage layer 30. The blocking insulating layer 40 may include a first oxide layer 42, a high-k dielectric layer 44, and a second oxide layer 46 that are stacked sequentially.

The first and second oxide layers 42 and 46 may be formed of the same material and may have the same internal structure. For example, each of the first and second oxide layers 42 and 46 may be a high-temperature oxide (HTO) layer, which is formed by high-temperature oxidation using SiH₂Cl₂ and H₂O gases as source gases. The HTO layer has a high breakdown voltage and a time-dependent dielectric breakdown (TDDB) characteristic. However, the present invention is not limited thereto.

As shown in FIG. 1, in some embodiments, a first thickness t₁ of the first oxide layer 42 is different from a second thickness t₂ of the second oxide layer 46. In particular, the first thickness t₁ of the first oxide layer 42 may be greater than the second thickness t₂ of the second oxide layer 46. More specifically, the first thickness t₁ of the first oxide layer 42 may be more than 1.0 times as great as the second thickness t₂ of the second oxide layer 46. Also, each of the first thickness t₁ of the first oxide layer 42 and the second thickness t₂ of the second oxide layer 46 may range from about 25 Å to about 75 Å. Characteristics of the non-volatile memory device 100 caused by a difference between the first thickness t₁ of the first oxide layer 42 and the second thickness t₂ of the second oxide layer 46 will be described in detail below.

The high-k dielectric layer 44 is disposed between the first and second oxide layers 42 and 46. The high-k dielectric layer 44 may include a dielectric material having a higher dielectric constant than either of the first and second oxide layers 42 and 46. Specifically, the high-k dielectric layer 44 may be formed of a material having a dielectric constant of 8 or higher. The high-k dielectric layer 44 may be a single layer including aluminum oxide (Al₂O₃), yttrium oxide (Y₂O₃), zirconium silicon oxide (ZrSiₓO_{y}), hafnium silicon oxide (HfSiₓO_{y}), lanthanum oxide (La₂O₃), zirconium oxide (ZrO₂), hafnium oxide (HfO₂), tantalum oxide (Ta₂O₃), praseodymium oxide (Pr₂O₃), and/or titanium oxide (TiO₂). Alternatively, the high-k dielectric layer 44 may be a multiple layer obtained by stacking a plurality of layers, each layer including aluminum oxide (Al₂O₃), yttrium oxide (Y₂O₃), zirconium silicon oxide (ZrSiₓO_{y}), hafnium silicon oxide (HfSiₓO_{y}), lanthanum oxide (La₂O₃), zirconium oxide (ZrO₂), hafnium oxide (HfO₂), tantalum oxide (Ta₂O₃), praseodymium oxide (Pr₂O₃), and/or titanium oxide (TiO₂). The bandgap of the high-k dielectric layer 44 may be lower than that of silicon oxide. The following Table 1 shows the dielectric constants, bandgaps, and crystal structures of high-k dielectric materials that may form the high-k dielectric layer 44.

TABLE 1

| | Dielectric | | |
|---|---|---|---|
| Material | constant | Bandgap (eV) | Crystal structure |
| SiO₂ | 3.9 | 8.9 | Amorphous |
| Si₃N₄ | 7 | 5.1 | Amorphous |
| Al₂O₃ | 10 | 8.0 | Amorphous |
| Y₂O₃ | 12-14 | 5.6 | Cubical |
| ZrSiₓO_{y} | 12-22 | 6.5 | — |
| HfSiₓO_{y} | 15-25 | 6.5 | — |
| La₂O₃ | 20 | 4.0 | Hexagonal, cubical |
| ZrO₂ | 22 | 7.8 | Monoclinic, orthorhombic, cubical |
| HfO₂ | 25 | 6.0 | monoclinic, orthorhombic, cubical |
| Ta₂O₃ | 26 | 4.4 | Orthorhombic |
| Pr₂O₃ | 31 | — | — |
| TiO₂ | 80 | 2.3 | Tetragonal, rutile, anatase |

The high-k dielectric layer 44 may be formed to a thickness of about 30 to 100 Å using an atomic layer deposition (ALD) process and/or a CVD process. However, the formation method, layer structure, thickness, and material of the high-k dielectric layer 44 are only described as examples, and the present invention is not limited thereto.

An ALD process of forming the high-k dielectric layer 44 will now be described. In some embodiments, the high-k dielectric layer 44 may be a double layer having a HfO₂ layer and an Al₂O₃ layer. The formation of such a high-k dielectric layer 44 using the ALD process can include: 1) depositing an Hf layer; 2) purging an ALD chamber using N₂ gas; 3) oxidizing the Hf layer using O₃ gas; 4) purging the ALD chamber using N₂ gas; 5) depositing an Al layer, 6) purging the ALD chamber using N₂ gas; 7) oxidizing the Al layer using O₃ gas; and 8) purging the ALD chamber using N₂ gas. Specifically, Hf gas is injected into the ALD chamber to deposit the Hf layer on a wafer. N₂ gas is injected into the ALD chamber to purge the remaining Hf source gas. O₃ gas is injected into the ALD chamber to oxidize the deposited Hf layer, thereby forming an HfO₂ layer. N₂ gas is injected again into the ALD chamber to purge the remaining O₃ gas. Thereafter, an Al source gas is injected into the ALD chamber to deposit an Al layer on the HfO₂ layer. N₂ gas is injected to purge the remaining Al source gas. Subsequently, O₃ gas is injected into the ALD chamber to oxidize the Al layer deposited on the HfO₂ layer, thereby forming an Al₂O₃ layer. N₂ gas is injected into the ALD chamber to purge the remaining O₃ gas. During the ALD process, the ALD chamber may be maintained at a temperature of 200 to 400° C. under a pressure of about 10 to 100 Torr. However, the formation methods, materials, and/or process conditions of the high-k dielectric layer 44 are only described as examples, and the present invention is not limited thereto.

Source gases used for the ALD process may be metal precursors containing high-k dielectric metals. For example, the source gases may be aluminum precursors, such as Al₂O₃ and Al(CH₃)₃.H₂O, hafnium precursors, such as HfO₂ and HfCl₄.H₂O, zirconium precursors, such as ZrO₂ and ZrCl₄.H₂O, tantalum precursors, such as TaO₂ and TaCl₅.H₂O, and/or titanium precursors, such as TiO₂ and TiCl₄.H₂O.

Also, an annealing process may be optionally performed in order to densify the high-k dielectric layer 44 and supply additional oxygen. The annealing process may be performed using a furnace-type process, a rapid temperature process (RTP), and/or a rapid-temperature anneal (RTA). Furthermore, the annealing process may be performed in an atmosphere containing O₃, Ar, N₂, and/or O₂. The annealing process may be performed at a temperature of about 100° C. to about 400° C. with a power of about 100 W to about 1000 W for 10 to 60 seconds. However, the present invention is not limited to the above description.

In the above-described process, the blocking insulating layer 40 including a stack in which the first oxide layer 42, the high-k dielectric layer 44, and the second oxide layer 46 that are stacked sequentially is completed.

The control gate 50 is disposed on the second oxide layer 46 of the blocking insulating layer 40. The control gate 50 may be formed using a CVD process. Also, the control gate 50 may include Al, Ru, TaN, TiN, W, WN, HfN, WSiₓ, and/or a combination of any of the foregoing. The control gate 50 may be formed to a thickness of about 500 to 2000 Å. However, the formation methods, layer structures, thicknesses, and materials of the control gate 50 are only described as examples and the present invention is not limited thereto.

Although a flash memory device including a dielectric layer is described in the embodiments of the present invention, the present invention can be applied to non-volatile memory devices including dielectric layers, such as EEPROMs and EPROMs. Also, the present invention can be applied to all methods of fabricating sub-70-nm flash memory devices using a self aligned-shallow trench isolation (SA-STI) process or a self aligned floating gate (SAFG) process.

The present invention is not limited to the above-described flash memory device, and can be applied not only to other non-volatile memory devices, but also to multi-bit flash memory devices that perform erase operations using control gate electrodes.

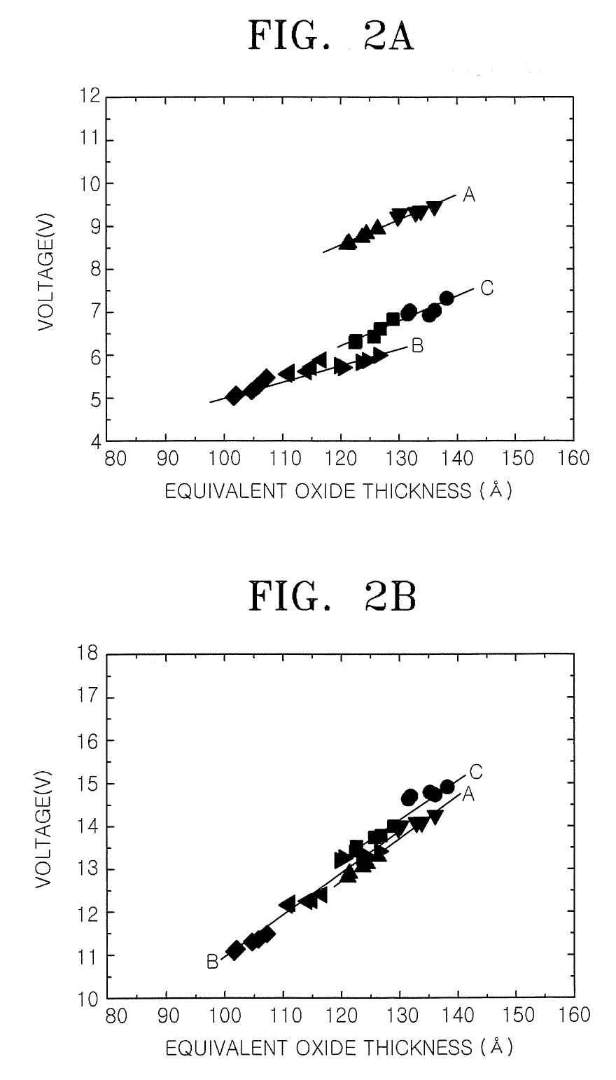

Cell characteristics of the non-volatile memory device shown in FIG. 1, which includes the blocking insulating layer 40 having the first oxide layer 42, the high-k dielectric layer 44, and the second oxide layer 46 in which the first oxide layer 42 is thicker than the second oxide layer 46 will be described in detail with reference to FIGS. 2A through 6B.

In FIGS. 2A through 6B, reference character A denotes a non-volatile memory cell in which the first oxide layer 42 is thicker than the second oxide layer 46 as in the non-volatile memory device shown in FIG. 1. In this case, the first oxide layer 42 has a thickness 1.2 times greater than the thickness of the second oxide layer 46. Reference character B denotes a non-volatile memory cell in which the first oxide layer 42 is as thick as the second oxide layer 46. Reference character C denotes a non-volatile memory cell in which the first oxide layer 42 is thinner than the second oxide layer 46. In this case, the second oxide layer 46 has a thickness 1.2 times greater than the thickness of the first oxide layer 42. Also, reference characters A, B, and C denote the non-volatile memory cells in which the blocking insulating layer 40 includes the high-k dielectric layer 44 formed of aluminum oxide (Al₂O₃). Reference character D denotes a non-volatile memory cell in which the blocking insulating layer 40 includes an ONO layer including a nitride layer instead of the high-k dielectric layer 44 and the first oxide layer 42 is thicker than the second oxide layer 46. Reference character E denotes a non-volatile memory cell in which the blocking insulating layer 40 includes an ONO layer including a nitride layer instead of the high-k dielectric layer 44 and the first oxide layer 42 is thinner than the second oxide layer 46.

FIGS. 2A and 2B are graphs of an applied voltage relative to equivalent oxide thickness (EOT) under a low leakage current condition and a high leakage current condition, respectively, which are obtained after a leakage current is measured according to an applied voltage. Here, EOT does not mean a physical thickness of a blocking insulating layer but a calculated thickness in terms of the thickness of silicon oxide calculated with respect to a dielectric constant of the silicon oxide.

Referring to FIG. 2A, when EOT was maintained constant under the low leakage current condition, the memory cell A according to embodiments of the present invention required a higher voltage than the other memory cells B and C. When a memory cell requires a high applied voltage, the leakage current may be low. Therefore, it can be seen that the memory cell A may have a good data retention characteristic. Thus, it can be concluded that the non-volatile memory device in which the first oxide layer 42 is thicker than the second oxide layer 46 has an excellent data retention characteristic.

Referring to FIG. 2B, when a voltage of 10V or higher was applied under the high leakage current voltage condition, the memory cells A, B, C may show little difference.

However, a typical flash memory device may employ a program/erase voltage of about 20V, a turn-on voltage of about 6 to 7V, and a retention voltage of about 1V. Accordingly, in a flash memory device, a leakage current may be more effectively reduced during a low-voltage operation, such as a turn-on operation or a retention operation, than during a high-voltage operation, for example, a program operation or an erase operation. Therefore, as described above, the non-volatile memory device shown in FIG. 1 in which the first oxide layer 42 is thicker than the second oxide layer 46 can exhibit a low leakage current during a low-voltage operation, for example, a turn-on operation, and may have a good data retention characteristic.

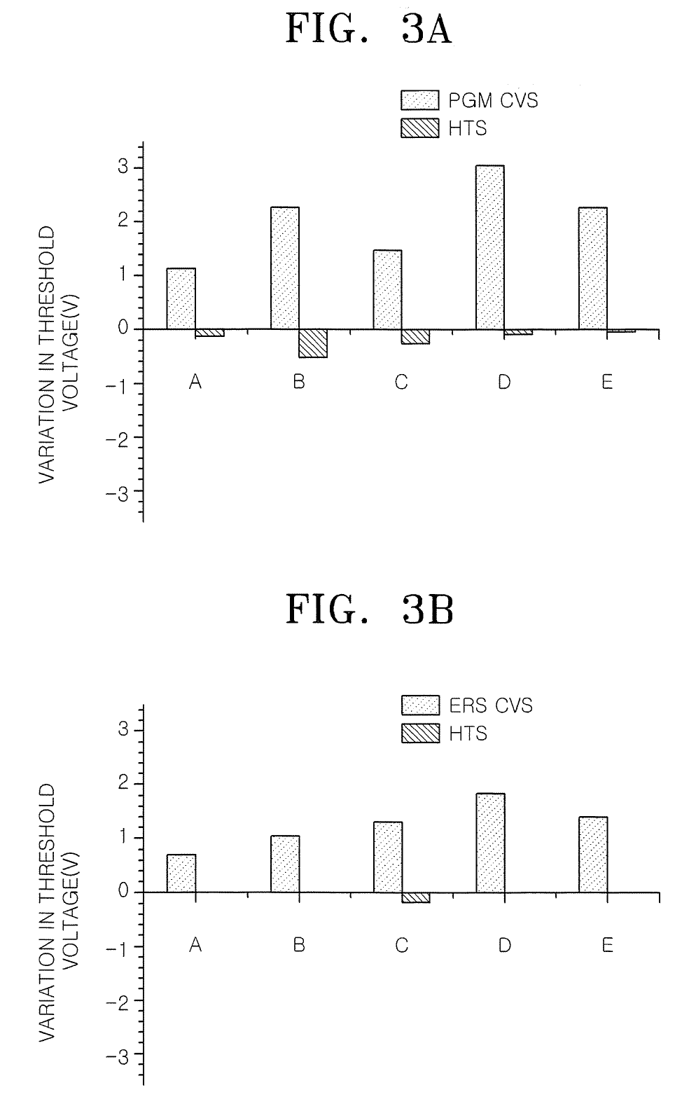

FIG. 3A is a graph of a variation in a threshold voltage measured after a constant voltage stress (CVS) test and a high-temperature stability (HTS) test are performed during a program operation, and FIG. 3B is a graph of a variation in a threshold voltage measured after a CVS test and an HTS test are performed during an erase operation. In order to test the reliability of a non-volatile memory device, a variation in a threshold voltage was measured after a constant voltage is applied using the CVS test and a high-temperature treatment is performed at a temperature of about 200° C. using the HTS test and represented graphically in FIGS. 3A and 3B.

Referring to FIGS. 3A and 3B, as compared with the memory cells D and E in which the blocking insulating layer 40 includes the ONO layer, the memory cells A, B, and C in which the blocking insulating layer 40 includes the high-k dielectric layer 44 exhibited smaller variations in the threshold voltage during the program and erase operations after the CVS and HTS tests were performed. Therefore, it can be seen that the memory cells A, B, and C in which the blocking insulating layer 40 includes the high-k dielectric layer 44 are more stable than the memory cells D and E. Also, as compared with the memory cells B and C, the memory cell A according to embodiments of the present invention showed lower variations in the threshold voltage during both the program and erase operations after the CVS and HTS tests were performed. Therefore, the non-volatile memory cell A according to embodiments of the present invention, in which the first oxide layer 42 is thicker than the second oxide layer 46, may be highly stable during both program and erase operations after the CVS and HTS tests are performed.

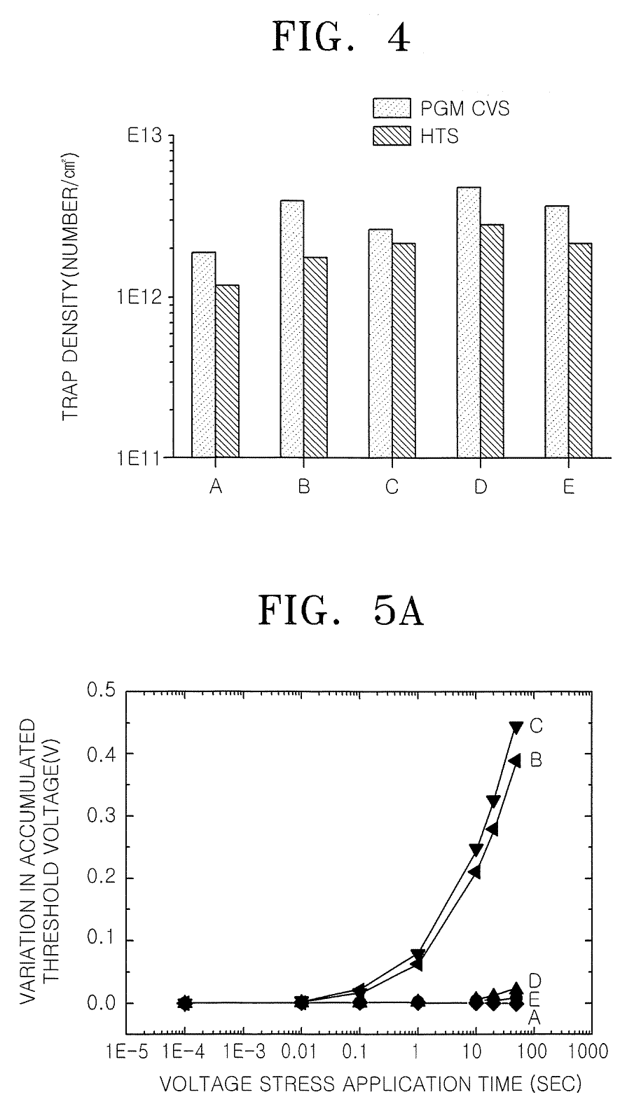

FIG. 4 is a graph of a trap density measured during program and erase operations.

Referring to FIG. 4, as compared with the memory cells D and E in which the blocking insulating layer 40 includes the ONO layer, the memory cells A, B, and C in which the blocking insulating layer 40 includes the high-k dielectric layer 44 had lower trap densities during both the program and erase operations. Also, as compared with the memory cells B and C, the memory cell A according to embodiments of the present invention had lower trap densities during both the program and erase operations. When a memory cell has a high trap density, more charges are trapped in the memory cell, which can change the threshold voltage, thereby deteriorating the operating characteristics of the non-volatile memory device. Therefore, it can be concluded that the non-volatile memory cell A according to embodiments of the present invention, in which the first oxide layer 42 is thicker than the second oxide layer 46 may have relatively low trap densities during both the program and erase operations and may have excellent operating characteristics.

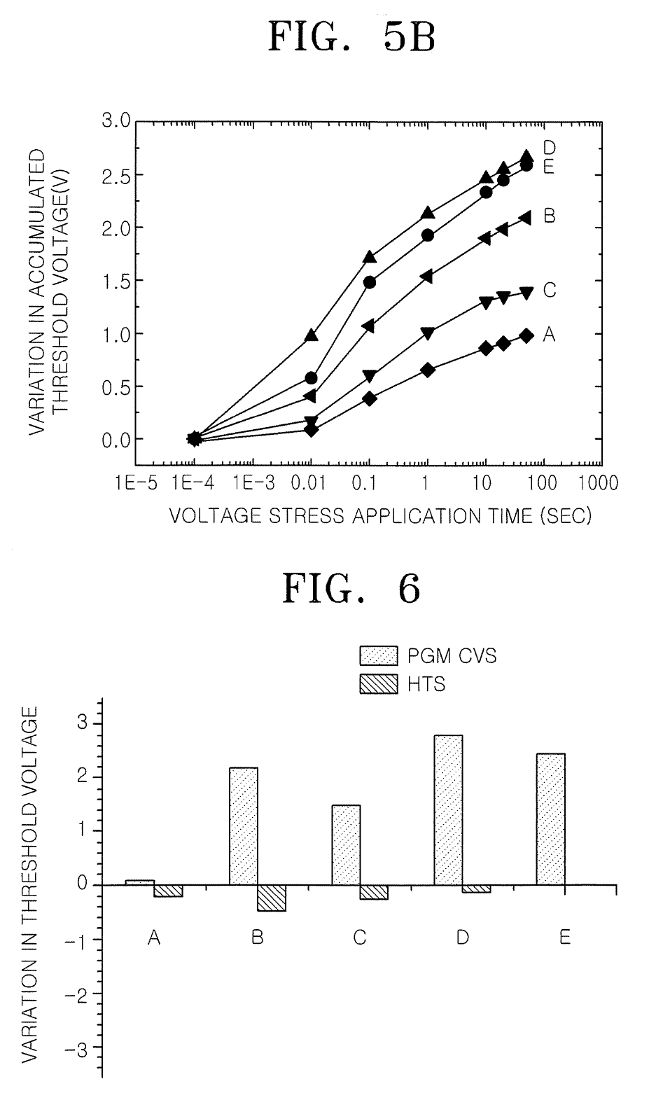

FIG. 5A is a graph of a variation in an accumulated threshold voltage relative to a voltage stress application time when a low voltage is applied during a program operation, and FIG. 5B is a graph of a variation in an accumulated threshold voltage relative to a voltage stress application time when a high voltage is applied during an erase operation.

Referring to FIG. 5A, unlike results shown in FIGS. 3A and 3B, when a low voltage was applied, the memory cells B and C in which the blocking insulating layer 40 includes the high-k dielectric layer 44 had relatively large variations in the accumulated threshold voltage. In comparison, the memory cell A in which the blocking insulating layer 40 includes the high-k dielectric layer 44 has about the same variation in the threshold voltage as the memory cells D and E in which the blocking insulating layer 40 includes the ONO layer. However, referring to FIG. 5B, when a high voltage was applied, the memory cells D and E had relatively large variations in the accumulated threshold voltage compared to the memory cells A, B, and C. Thus, it can be seen that as compared with the other memory cells B, C, D, and E, the memory cell A according to embodiments of the present invention can exhibit smaller variations in the threshold voltage relative to the voltage stress application time when the low and high voltages are applied. Therefore, when a voltage is continuously applied, the memory cell A according to embodiments of the present invention in which the first oxide layer 42 is thicker than the second oxide layer 46 may be more stable during program operation.

FIG. 6 is a graph of a variation in a threshold voltage when the polarity of an applied voltage is periodically reversed, that is, when program operations and erase operations are performed periodically during a cycle of 1.2K. In FIG. 6, CVS and HTS tests were performed under the same conditions as in FIGS. 3A and 3B.

Referring to FIG. 6, when the program and erase operations are repeated during the cycle of 1.2K, as compared with the memory cells D and E in which the blocking insulating layer 40 includes the ONO layer, the memory cells A, B, and C in which the blocking insulating layer 40 includes the high-k dielectric layer 44 exhibited smaller variations in the threshold voltage after the CVS and HTS tests were performed. Thus, it can be seen that a memory cell in which a blocking insulating layer includes a high-k dielectric layer may be highly stable during repetition of the program and erase operations after the CVS and HTS tests are performed. Also, when the program and erase operations are repeated during the cycle of 1.2K, as compared with the memory cells B and C, the memory cell A according to embodiments of the present invention may show smaller variations in the threshold voltage after the CVS and HTS tests are performed. Therefore, the non-volatile memory cell A according to some embodiments of the present invention, in which the first oxide layer 42 is thicker than the second oxide layer 46, may be highly stable during the repetition of the program and erase operations after the CVS and HTS tests are performed.

As described above, a non-volatile memory device according to some embodiments of the present invention includes the blocking insulating layer having a high-k dielectric layer, thereby increasing a coupling ratio. Also, as the coupling ratio increases, the program and erase speeds of the non-volatile memory device can increase. Furthermore, since the blocking insulating layer is formed by stacking the silicon oxide layer and the high-k dielectric layer, it may be easy to control the coupling ratio.

According to some embodiments, the blocking insulating layer is formed such that the first oxide layer (i.e., a lower oxide layer) is thicker than the second oxide layer (i.e., an upper oxide layer), so that the coupling ratio can be increased and a leakage current can be effectively reduced. In particular, a non-volatile memory device according to some embodiments can effectively reduce a leakage current in a low-voltage operation region. Due to the excellent leakage current reduction characteristic, a non-volatile memory device according to embodiments of the present invention can have good data retention characteristics and/or high device reliability.

A non-volatile memory device according to some embodiments of the present invention may have high device stability because a variation in a threshold voltage may be small during program and/or erase operations even after the CVS and HTS tests are performed. Also, a non-volatile memory device according to some embodiments of the present invention may have low trap densities during both program and erase operations, so that the non-volatile memory device may have excellent operating characteristics. Furthermore, since a variation in an accumulated threshold voltage is also small according to a voltage stress application time, when a voltage is continuously applied, a non-volatile memory device according to some embodiments of the present invention may have high device stability. In addition, when program and erase operations are repeated and CVS and HTS tests are performed, a non-volatile memory device according to some embodiments of the present invention can show a small variation in a threshold voltage, so it can be seen that the non-volatile memory device may have high device stability.

Therefore, a non-volatile memory device according to some embodiments of the present invention can reduce the occurrence of a leakage current caused when a blocking insulating layer is formed to have a small thickness, so that a physical thickness of the blocking insulating layer can be reduced. Also, since the blocking insulating layer is formed by stacking a silicon oxide layer and a high-k dielectric layer, a coupling ratio can be easily controlled.

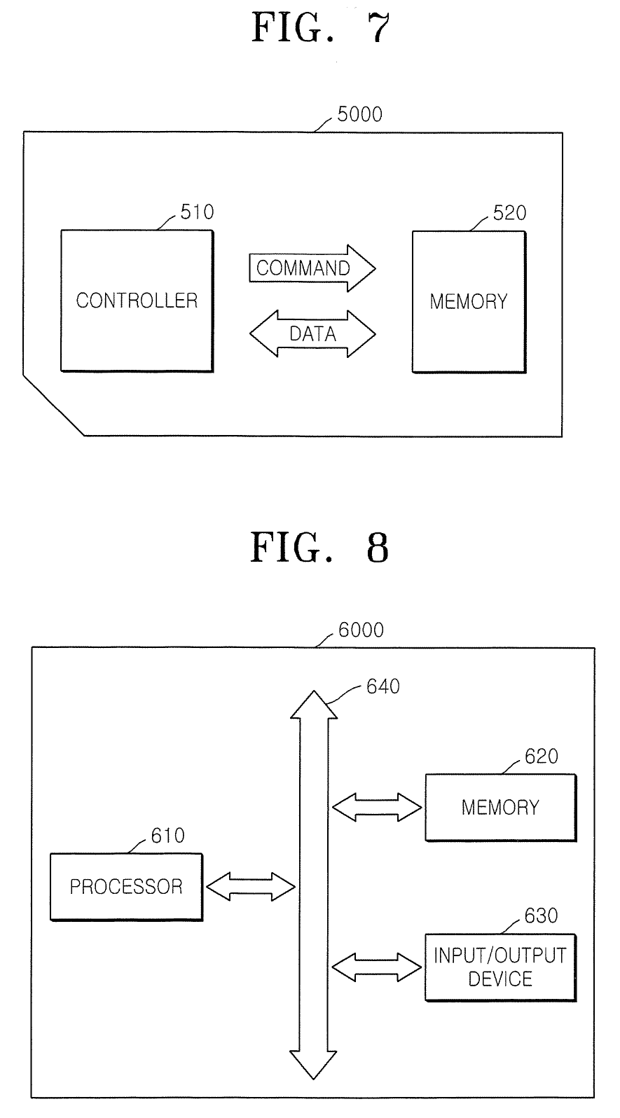

FIG. 7 is a schematic view illustrating a memory card 5000 according to some embodiments of the present invention.

Referring to FIG. 7, a controller 510 and a memory 520 are configured to send and receive electric signals to/from each other. For example, when the controller 510 gives a command to the memory 520, the memory 520 can send data. The memory 520 can include the flash memory device 100 of FIG. 3. Flash memory devices according to the various embodiments of the present invention can be disposed in NAND or NOR architecture arrays in correspondence to the logic gate design, wherein such NAND and NOR arrays are generally known in the art. The memory arrays disposed in a plurality of rows and columns can have one or more memory array banks. The memory 520 can include the memory array or the memory array bank, all of which are known in the art. The memory card 5000 can further include conventional members, such as a conventional row decoder, a column decoder, input/output (I/O) buffers, and/or a control resistor in order to drive the memory array bank, all of which are known in the art. The memory card 5000 can be used in memory devices as a memory card, for example, such as a memory stick card, a smart media (SM) card, a secure digital (SD) card, a mini SD card, or a multi media card (MMC).

FIG. 8 is a schematic view illustrating a system 6000 according to some embodiments of the present invention.

Referring to FIG. 8, a processor 610, an input/output(l/O) apparatus 630, and a memory 620 can perform data communication using a bus 640. The processor 610 executes a software program and controls the system 6000. The input/output apparatus 630 can be used to input or output data of the system 6000. The system 6000 is connected to an external apparatus, for example, a personal computer or a network, using the input/output apparatus 630, to send and receive data to and from the external apparatus. The memory 620 can include the flash memory device 100 of FIG. 3. For example, the memory 620 can store codes and/or data for operating the processor 610. For example, the system 6000 can be used for a mobile phone, a MP3 player, a navigation system, a portable multimedia player (PMP), a solid state disk (SSD), a household appliance, etc.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A non-volatile memory device, comprising:
a semiconductor layer including source and drain regions and a channel region between the source and drain regions;
a tunneling insulating layer on the channel region of the semiconductor layer;
a charge storage layer on the tunneling insulating layer;
a blocking insulating layer on the charge storage layer and including a first oxide layer with a first thickness on the charge storage layer, a second oxide layer on the first oxide layer, the second oxide layer having a second thickness different from the first thickness, and a high-k dielectric layer between the first oxide layer and the second oxide layer; and
a control gate on the blocking insulating layer.

2. The device of claim 1, wherein the first thickness is greater than the second thickness.

3. The device of claim 1, wherein the first thickness is more than 1.0 times as great as the second thickness.

4. The device of claim 1, wherein the first thickness is about 25 Å to about 80 Å.

5. The device of claim 1, wherein the second thickness ranges from about 25 Å to about 80 Å.

6. The device of claim 1, wherein the high-k dielectric layer comprises a dielectric material having a higher dielectric constant than the first and second oxide layers.

7. The device of claim 1, wherein the high-k dielectric layer comprises a dielectric material having a dielectric constant of 8 or higher.

8. The device of claim 1, wherein the high-k dielectric layer comprises a single layer comprising aluminum oxide (Al₂O₃), yttrium oxide (Y₂O₃), zirconium silicon oxide (ZrSiₓO_{y}), hafnium silicon oxide (HfSiₓO_{y}), lanthanum oxide (La₂O₃), zirconium oxide (ZrO₂), hafnium oxide (HfO₂), tantalum oxide (Ta₂O₃), praseodymium oxide (Pr₂O₃), and/or titanium oxide (TiO₂).

9. The device of claim 1, wherein the high-k dielectric layer comprises a single layer comprising at least two materials selected from the group consisting of aluminum oxide (Al₂O₃), yttrium oxide (Y₂O₃), zirconium silicon oxide (ZrSiₓO_{y}), hafnium silicon oxide (HfSiₓO_{y}), lanthanum oxide (La₂O₃), zirconium oxide (ZrO₂), hafnium oxide (HfO₂), tantalum oxide (Ta₂O₃), praseodymium oxide (Pr₂O₃), and titanium oxide (TiO₂).

10. The device of claim 1, wherein the high-k dielectric layer comprises a plurality of layers, each of the plurality of layers comprising aluminum oxide (Al₂O₃), yttrium oxide (Y₂O₃), zirconium silicon oxide (ZrSiₓO_{y}), hafnium silicon oxide (HfSiₓO_{y}), lanthanum oxide (La₂O₃), zirconium oxide (ZrO₂), hafnium oxide (HfO₂), tantalum oxide (Ta₂O₃), praseodymium oxide (Pr₂O₃), and/or titanium oxide (TiO₂).

11. The device of claim 1, wherein the high-k dielectric layer has a lower bandgap than silicon oxide.

12. The device of claim 1, wherein the high-k dielectric layer has a thickness of about 30 Å to about 100 Å.

13. The device of claim 1, wherein the tunneling insulating layer comprises a silicon oxide (SiO₂) layer, a silicon nitride (Si₃N₄) layer, a silicon oxynitride (SiON) layer, a hafnium oxide (HfO₂) layer, a hafnium silicon oxide (HfSiₓO_{y}) layer, an aluminum oxide (Al₂O₃) layer, a zirconium oxide (ZrO₂) layer, and/or a combination thereof.

14. The device of claim 1, wherein the charge storage layer comprises a floating gate or a charge trap layer.

15. The device of claim 14, wherein the charge storage layer comprises a floating gate comprising polysilicon.

16. The device of claim 14, wherein the charge trap layer comprises a silicon oxide (SiO₂) layer, a silicon nitride (Si₃N₄) layer, a silicon oxynitride (SiON), a hafnium oxide (HfO₂) layer, a zirconium oxide (ZrO₂) layer, a tantalum oxide (Ta₂O₃) layer, a titanium oxide (TiO₂) layer, a hafnium aluminum oxide (HfAlₓO_{y}) layer, a hafnium tantalum oxide (HfTaₓO_{y}) layer, a hafnium silicon oxide (HfSiₓO_{y}) layer, an aluminum nitride (AlₓN_{y}) layer, and/or an aluminum gallium nitride (AlGaN) layer.

17. The device of claim 1, wherein the control gate comprises polysilicon, Al, Ru, TaN, TiN, W, WN, HfN, WSiₓ, and/or a combination thereof.

18. The device of claim 1, wherein the semiconductor layer comprises silicon, silicon-on-insulator (SOI), silicon-on-sapphire, germanium, silicon-germanium, and/or gallium-arsenide.

19. A card, comprising:
a memory comprising a non-volatile memory device comprising:
a semiconductor layer including source and drain regions and a channel region between the source and drain regions;
a tunneling insulating layer on the channel region of the semiconductor layer;
a charge storage layer on the tunneling insulating layer;
a blocking insulating layer on the charge storage layer and comprising a first oxide layer with a first thickness on the charge storage layer, a second oxide layer on the first oxide layer, the second oxide layer having a second thickness different from the first thickness, and a high-k dielectric layer between the first oxide layer and the second oxide layer; and
a control gate on the blocking insulating layer; and
a controller configured to control the memory, including sending and receiving data to and from the memory.

20. A system, comprising:
a memory comprising a non-volatile memory device comprising:
a semiconductor layer including source and drain regions and a channel region between the source and drain regions;
a tunneling insulating layer on the channel region of the semiconductor layer;
a charge storage layer on the tunneling insulating layer;
a blocking insulating layer on the charge storage layer and comprising a first oxide layer with a first thickness on the charge storage layer, a second oxide layer on the first oxide layer, the second oxide layer having a second thickness different from the first thickness, and a high-k dielectric layer between the first oxide layer and the second oxide layer; and
a control gate on the blocking insulating layer;
a processor configured to send and receive data to and from the memory via a bus; and
an input/output device configured to send and receive data to and from the bus.
